(19) United States
(12) Patent Application Publication
(10) Pub. No.: US 2025/0047257 A1
(43) Pub. Date: Feb. 6, 2025

(54) BASE FOR PIEZOELECTRIC DEVICE, MANUFACTURING METHOD THEREFOR, AND PIEZOELECTRIC DEVICE

(71) Applicant: NIHON DEMPA KOGYO CO., LTD., Tokyo (JP)

(72) Inventor: Shuichi MIZUSAWA, Saitama (JP)

(73) Assignee: NIHON DEMPA KOGYO CO., LTD., Tokyo (JP)

(21) Appl. No.: 18/780,392

(22) Filed: Jul. 22, 2024

(30) Foreign Application Priority Data
Aug. 3, 2023 (JP) 2023-126693

(51) Int. Cl. H03H 9/10; H03H 3/02; H03H 9/19

(52) U.S. Cl. CPC H03H 9/1021; H03H 3/02; H03H 9/19; H03H 2003/022

(57) ABSTRACT

A base includes a first substrate, a contact hole and a contact hole wiring, a first metal film, a second substrate, a second metal film, and a routing wiring. The second substrate is formed of a material identical to a material of the first substrate and bonded to the first substrate by intermetallic bonding. The second metal film is disposed on a third surface as a surface of the second substrate on the first substrate side and constitutes the intermetallic bonding cooperatively with the first metal film. The routing wiring reaches a fourth surface of the second substrate as an opposite surface of the third surface from the contact hole wiring via the third surface and a side surface of the second substrate. The contact hole has an opening area on a second surface side larger than an opening area on a first surface side.

### CROSS-REFERENCE TO RELATED APPLICATIONS

This application is based on and claims priority under 35 U.S.C. § 119 to Japanese Patent Application No. 2023-126693, filed on Aug. 3, 2023, the entire content of which is incorporated herein by reference.

### TECHNICAL FIELD

This disclosure relates to a base for a piezoelectric device and the piezoelectric device using the base.

### DESCRIPTION OF THE RELATED ART

In piezoelectric devices, a container for containing a piezoelectric element is indispensable. Thus, for quartz crystal devices as one kind of piezoelectric device, various containers, such as a metal container, a ceramic container, and a container using glass or crystal, have been used or studied. Especially for mass production type quartz crystal devices, since demand for surface mount type quartz crystal devices is high, surface mount type containers are frequently used.

A typical container suitable for the surface mount type and mass production is a ceramic container. Specifically, it is a container in which a ceramic base and a lid made of metal or ceramic are bonded together. The ceramic base is typically a base in which a bottom plate having a rectangular shape in plan view formed of a ceramic material and a dike portion formed of a ceramic material laminated on the bottom plate are integrally fired (for example, paragraph 26, FIG. 1, and the like of Japanese Unexamined Patent Application Publication No. 2007-274071).

In the current situation, the ceramic base is most excellent as a base for a piezoelectric device. However, as thinning and downsizing of the piezoelectric devices advance, the ceramic base has limitations in terms of structure, accuracy, and cost. Consequently, a base having a novel structure that can substitute for the ceramic base has been desired.

In order to respond to the demand, the inventor for this application proposed a base for a piezoelectric device having a structure in which two crystal substrates are bonded together using intermetallic bonding and having a wiring structure in which wirings are disposed using a bonding boundary, a side surface, and the like of the two crystal substrates (Japanese Unexamined Patent Application Publication No. 2022-145456).

While this base can be expected as a base for a piezoelectric device, a further improved wiring structure is desired.

A need thus exists for a base for a piezoelectric device and the piezoelectric device which are not susceptible to the drawback mentioned above.

### SUMMARY

According to an aspect of this disclosure, there is provided a base for a piezoelectric device as a first disclosure of the application. The base includes a first substrate, a contact hole and a contact hole wiring, a first metal film, a second substrate, a second metal film, and a routing wiring. The first substrate has a first surface and a second surface opposed to the first surface, and is formed of glass or crystal. The contact hole and the contact hole wiring extend from the first surface to the second surface. The first metal film is disposed in a region including a peripheral region of the contact hole on the second surface. The second substrate is formed of a material identical to a material of the first substrate and bonded to the first substrate by intermetallic bonding. The second metal film is disposed on a third surface as a surface of the second substrate on the first substrate side. The second metal film constitutes the intermetallic bonding cooperatively with the first metal film. The routing wiring reaches a fourth surface of the second substrate as an opposite surface of the third surface via the contact hole wiring, the third surface, and a side surface of the second substrate. The contact hole has an opening area on the second surface side larger than an opening area on the first surface side.

### BRIEF DESCRIPTION OF THE DRAWINGS

The foregoing and additional features and characteristics of this disclosure will become more apparent from the following detailed description considered with reference to the accompanying drawings, wherein:

FIG. 1A and FIG. 1B are drawings for describing a base 10 of a first embodiment;

FIG. 2A to FIG. 2D are drawings for especially describing structures of a contact hole 11d, a contact hole wiring 11e, and a plating film 11ea of the base 10 of the first embodiment;

FIG. 3A to FIG. 3C are drawings for describing some examples of a first metal film and a second metal film;

FIG. 4A and FIG. 4B are drawings for especially describing a wiring route of the base 10 of the first embodiment;

FIG. 5A to FIG. 5D are drawings for describing a base 20 of a second embodiment;

FIG. 6A to FIG. 6C are drawings for describing a base 30 of a third embodiment;

FIG. 7A and FIG. 7B are drawings for describing a piezoelectric device 50 of the first embodiment;

FIG. 8A and FIG. 8B are drawings for describing a piezoelectric device 60 of the second embodiment;

FIG. 9A to FIG. 9D are drawings for describing an example of a method for manufacturing the base 20 of the second embodiment; and

FIG. 10A to FIG. 10D are drawings for describing the example of the method for manufacturing the base 20 of the second embodiment following FIG. 9A to FIG. 9D.

### DETAILED DESCRIPTION

The following describes embodiments of respective disclosures of a base, a piezoelectric device, and a method for manufacturing the base of this application with reference to the attached drawings. Each drawing used in the description is merely illustrated schematically for understanding these disclosures. In each drawing used in the description, same reference numerals designate similar components, and their explanations are omitted in some cases. Shapes, dimensions, materials, and similar factors described in the following embodiments are merely preferred examples within the scope of this disclosure. Therefore, this disclosure is not limited to the following embodiments.

### 1. Embodiment of First Disclosure (Base)

### 1-1. Base 10 of First Embodiment

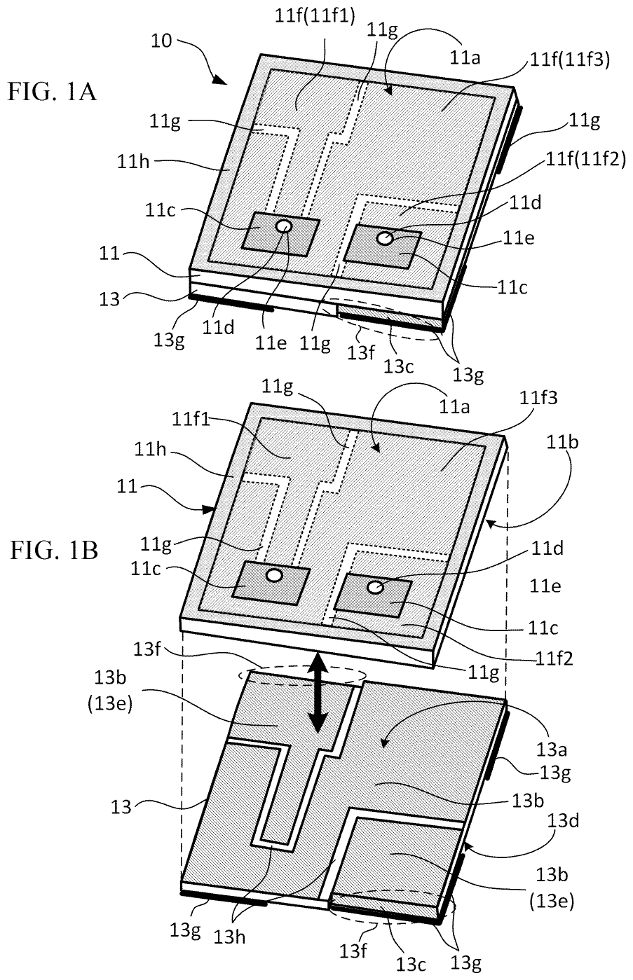

FIG. 1A and FIG. 1B are drawings for describing a base 10 of a first embodiment. FIG. 1A is especially a perspective view of the base 10, and FIG. 1B is especially an exploded perspective view illustrating the base 10 divided into a first substrate 11 and a second substrate 13.

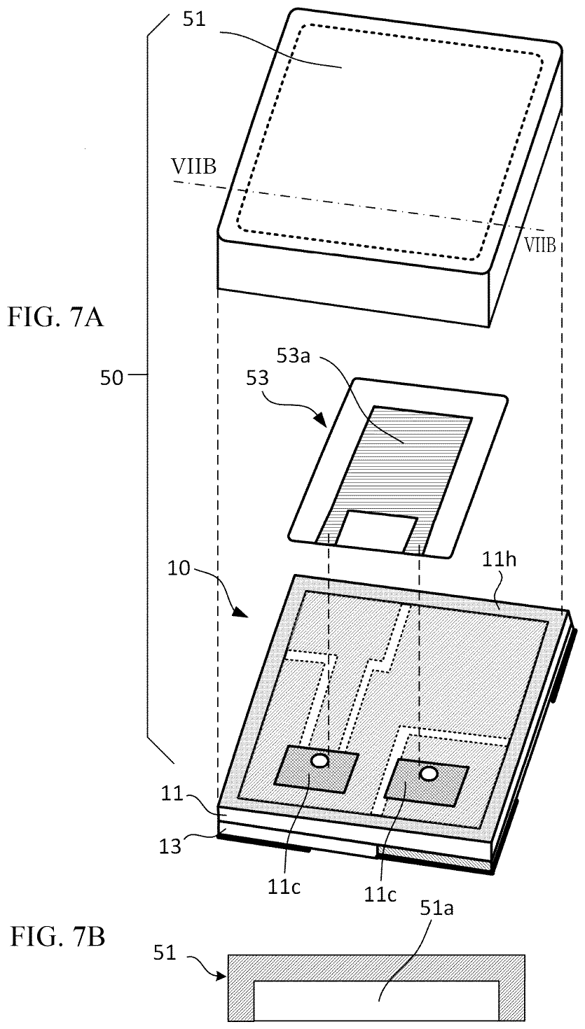

The base 10 of the first embodiment includes the first substrate 11, mounting pads 11c, contact holes 11d and contact hole wirings 11e, a first metal film 11f, insulation regions 11g, and a sealing pattern 11h. The first substrate 11 has a first surface 11a and a second surface 11b opposed thereto, and is formed of glass or crystal. The mounting pads 11c are disposed on the first surface 11a of the first substrate 11, and for a piezoelectric element (a piezoelectric element 53 illustrated in FIG. 7A and the like). The contact holes 11d and the contact hole wirings 11e extend from the first surface 11a to the second surface 11b. The first metal film 11f is disposed in a region including a peripheral region of the contact hole 11d on the second surface 11b.

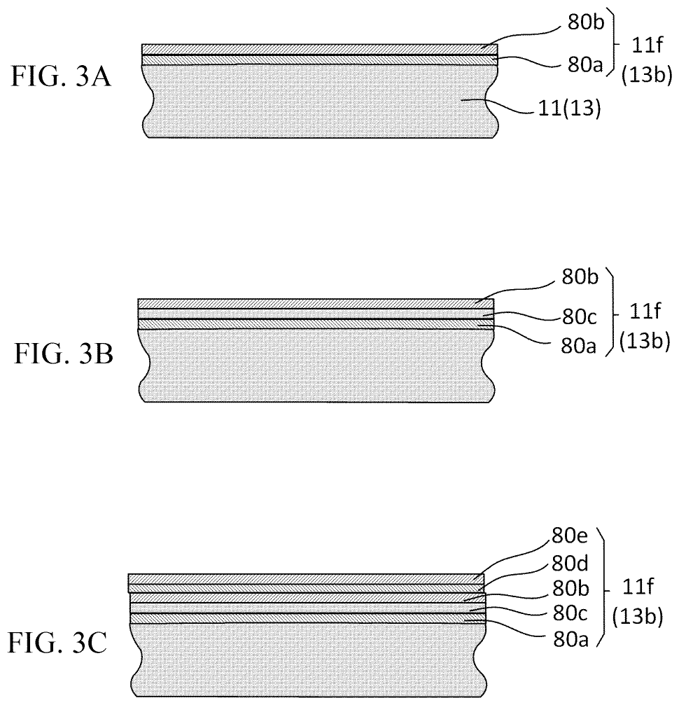

Furthermore, the base 10 includes the second substrate 13, a second metal film 13b, routing wirings 13e, castellations 13f, and external mounting terminals 13g (see FIG. 3A to FIG. 3C). The second substrate 13 is formed of a material identical to a material of the first substrate and bonded to the first substrate 11 by intermetallic bonding. The second metal film 13b is disposed on a third surface 13a as a surface of the second substrate 13 on the first substrate 11 side, and constitutes the intermetallic bonding cooperatively with the first metal film 11f, namely, by being bonded to the first metal film 11f. The routing wirings 13e reach a fourth surface 13d of the second substrate 13 as an opposite surface of the third surface 13a from the contact hole wirings 11e via the third surface 13a and side surfaces 13c of the second substrate 13. The castellations 13f are disposed on the side surfaces 13c of the second substrate 13 for the routing wirings 13e. The external mounting terminals 13g are disposed on the fourth surface 13d and connected to the routing wirings. The following describes specific examples of the respective components described above.

The first substrate 11 has, in a case of this example, a quadrilateral planar shape and a flat plate shape. A specific material of the first substrate 11 is preferably, for example, a Z-cut plate or an AT-cut plate of crystal. Each of the Z-cut plate and the AT-cut plate of crystal is a substrate mass-produced for a crystal unit, and thus also has an advantage in cost. When the specific material of the first substrate 11 is glass, any given preferred glass such as soda-lime glass may be used.

To the mounting pads 11c, a piezoelectric element is connected and fixed by a conductive adhesive or the like. The mounting pad 11c is electrically connected to the contact hole wiring 11e. The mounting pad 11c has any shape corresponding to a mounting structure of the piezoelectric element and is disposed at any location on the first surface 11a of the first substrate 11. In the case of this example, since a structure in which the piezoelectric element is held in a cantilever manner is illustrated, the mounting pads 11c are disposed at two locations that are in the proximity of one side of the first substrate 11 and that are spaced in a direction along the one side. The planar shape of the mounting pad 11c can be any shape such as a quadrilateral shape, a circular shape, or an elliptical shape. The mounting pad 11c can be formed of any given preferred metal film, for example, a laminated film of a chrome film and a gold film, or the like.

The contact holes 11d and the contact hole wirings 11e extend from the first surface 11a to the second surface 11b of the first substrate 11 and can be formed by using, for example, a photolithography technique, a wet etching technique, and a film forming technique on the first substrate 11. An example of a manufacturing method will be described later.

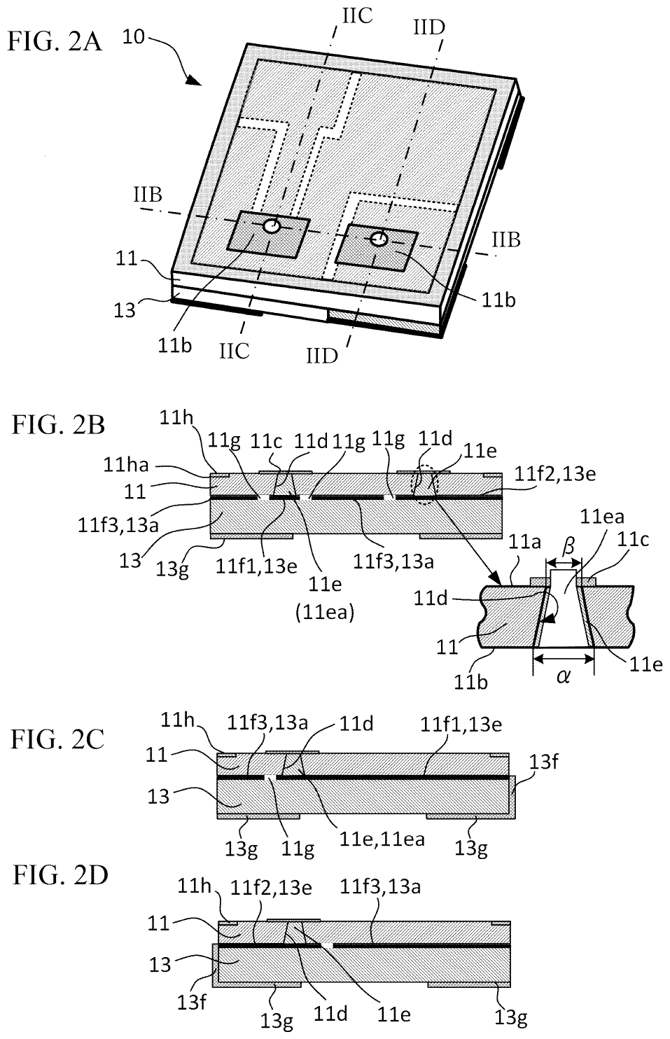

The structure of the contact hole 11d will be described in detail with reference to FIG. 2A to FIG. 2D. FIG. 2A is a perspective view of the base 10 similar to FIG. 1A. FIG. 2B to FIG. 2D are cross-sectional views along lines IIB-IIB, IIC-IIC, and IID-IID in FIG. 2A, respectively.

As illustrated in FIG. 2B to FIG. 2D, especially in a partially enlarged view in FIG. 2B, the contact hole 11d has an opening area α on the second surface 11b side of the first substrate 11 larger than an opening area β on the first surface 11a side. This is because, while details will be described later, with the configuration meeting α>β, the improvement of reliability of electrical connection in the whole wiring structure between an electrode of the piezoelectric element (an excitation electrode 53a illustrated in FIG. 7A and the like) and the external mounting terminal 13g of the base 10 can be more expected compared with the other case.

While the contact hole 11d has any planar shape such as a circular shape, an elliptical shape, and a quadrilateral shape, the planar shape is typically preferred to be a circular shape. The ratio between a and β may be, for example, 1.1≤α/β≤2, and is preferably 1.3≤α/β≤1.7. An excessively small ratio of α/β does not provide the above-described effect, and an excessively large ratio of α/β causes an obstacle to downsizing of the base 10 and reliability of airtightness. A constituent material of the contact hole wiring 11e can be, for example, any given preferred metal material similar to that of the mounting pad 11c.

In order to attempt more improvement of electrical reliability of the contact hole wiring 11e, as illustrated in the enlarged view in FIG. 2B, a superficial layer of the contact hole wiring 11e is preferably a plating film 11ea. The plating film 11ea may be any of an electrolytic plating film and an electroless plating film. A material of the plating film can also be any given preferred material, and for example, a nickel plating film is preferable. The plating film 11ea may be disposed on superficial layers of the contact hole wiring 11e and the mounting pad 11c connected thereto. The reason for providing the plating film 11ea is as follows. Since boundaries of the contact hole 11d with the first surface 11a and the second surface 11b have edge shapes, the coverage of wiring metal is generally poor. While the contact hole wiring 11e is typically formed by a film forming method, such as a sputtering method and an evaporation method, in a case of these film forming methods, since there is a limitation in increasing a film thickness, the coverage at the boundary edge is poor. Therefore, it is preferred that the plating film 11ea obtained as a thicker film compared with a film formed by the sputtering method or the like is provided to increase the coverage of the edge, thus attempting the improvement of reliability of the wiring structure.

In the base 10 of the first embodiment, the two contact holes 11d are linearly arranged to be parallel to the side of the first substrate 11. However, the planar positions of the contact holes 11d on the first substrate 11 are not limited thereto, and can be changed corresponding to the design of the piezoelectric device as necessary. For example, the contact holes 11d may be provided at positions on a diagonal line of the first substrate 11.

The first metal film 11f is one member for bonding the first substrate 11 and the second substrate 13 by intermetallic bonding and serves as one of sealing members for ensuring airtightness of the contact hole 11d. Thus, in the case of this example, the first metal film 11f is configured of three portions of a first portion 11f1 having a planar shape that surrounds the periphery of one of the two contact holes 11d, a second portion 11f2 having a planar shape that surrounds the periphery of the other of the two contact holes 11d, and a third portion 11f3 corresponding to the other region. Since the above-described three portions 11f1, 11f2, and 11f3 of the first metal film 11f are required to be mutually electrically separated, they are separated by the insulation regions 11g where the metal film is removed. However, in order to widen an intermetallic bonding area with the second metal film 13b, which will be described later, it is preferred to make the areas of the insulation regions 11g the minimum necessary.

On the other hand, the second metal film 13b disposed on the second substrate 13 side is the other member for bonding the first substrate 11 and the second substrate 13 by intermetallic bonding and serves as the other of the sealing members for ensuring airtightness of the contact holes 11d. Accordingly, the second metal film 13b is configured of three portions corresponding to the three portions 11f1, 11f2, and 11f3 of the first metal film 11f, and those three portions are separated by insulation regions 13h. It is preferred to make the areas of the insulation regions 13h the minimum necessary, similarly to the insulation regions 11g described above.

Here, respective materials of the first metal film 11f and the second metal film 13b will be described with reference to FIG. 3A to FIG. 3C. These drawings are cross-sectional views of a laminated body of the first substrate 11 (or the second substrate 13) and the first metal film 11f (or the second metal film 13b).

Each of the first metal film 11f and the second metal film 13b can be formed of any given preferred metal film where the intermetallic bonding can be performed. For example, it can be formed of a laminated film of a chrome film 80a and a gold film 80b, which are laminated in this order from the first substrate side (FIG. 3A). As a result, the first metal film 11f and the second metal film 13b can collaborate with one another to cause the intermetallic bonding between the gold films, and thus, the first substrate 11 and the second substrate 13 can be bonded by the intermetallic bonding. Alternatively, each of the first metal film 11f and the second metal film 13b may be formed of a laminated film of a titanium film and a gold film which are laminated in this order from the first substrate side.

More preferably, as illustrated in FIG. 3B, each of the first metal film 11f and the second metal film 13b is preferably formed of a three-layer structure laminated film of the chrome film 80a as a foundation film, a nickel film or nickel-tungsten alloy film 80c as an intermediate film, and the gold film 80b as an upper layer film. This is because forming the intermediate film with the nickel film or the nickel-tungsten alloy film allows reducing the diffusion of the chrome film as the foundation film into the gold film as the upper layer film, and thus, the intermetallic bonding by the first metal film and the second metal film can be more properly performed. It is considered that this three-layer structure laminated film can reduce the diffusion of chrome into the gold film over time.

More preferably, as illustrated in FIG. 3C, each of the first metal film 11f and the second metal film 13b is preferably formed of a five-layer structure metal film including a laminated film formed of a titanium film 80d and a gold film 80e laminated on the titanium film 80d, on the gold film 80b as the upper layer film of the above-described three-layer structure metal film. This is because since chrome sometimes diffuses into the gold film even when the nickel film or the nickel-tungsten alloy film is disposed, adding the titanium film allows reducing the diffusion of chrome into the gold film of the uppermost layer, and thus, the intermetallic bonding can be performed further properly. It is considered that this five-layer structure laminated film can also more reduce the diffusion of chrome into gold over time.

The sealing pattern 11h (FIG. 1A and FIG. 1B) is one for bonding a lid member (a lid member 51 illustrated in FIG. 7A and FIG. 7B, and the like) which will be described later to the base 10. The base 10 of the embodiment shows an example in which the lid member is bonded to the base with a brazing material, for example, a gold tin alloy. Accordingly, the sealing pattern 11h is formed of any given preferred material that is easily bonded to the gold tin alloy. The sealing pattern 11h is disposed along the edge of the first substrate 11 with a predetermined width.

When the sealing pattern 11h is disposed on the first surface 11a of the first substrate 11, as illustrated in FIG. 2B, it is preferred that a depressed portion 11ha having a depth equivalent to a thickness of the sealing pattern 11h is provided in a region of the first surface of the first substrate 11, where the sealing pattern 11h is to be provided, and the sealing pattern 11h is provided inside the depressed portion 11ha. This is because, while the thickness itself of the sealing pattern 11h sometimes become a problem in reducing the height when achieving a low profile type piezoelectric device is desired, forming a structure in which the sealing pattern 11h is embedded in the depressed portion 11ha as in this preferred example allows suppressing an increase of the piezoelectric device thickness due to the thickness of the sealing pattern 11h.

The second substrate 13 is bonded to the first substrate by the intermetallic bonding between the above-described first metal film and second metal film. The second substrate 13 is formed of a material identical to that of the first substrate 11 and has a planar shape approximately identical to that of the first substrate 11, and the second substrate 13 is a flat plate-shaped substrate. However, the planar shape of the second substrate 13 is slightly different from that of the first substrate 11 in that the castellations 13f are provided. The castellations 13f will be described later.

The routing wirings 13e are wirings that reach the fourth surface 13d from the contact hole wirings 11e, from the mounting pads 11c in a case of this embodiment, via the third surface 13a and the side surfaces 13c of the second substrate 13. However, the routing wirings 13e are formed by using a part of the first metal film 11f and the second metal film 13b. Specifically, the routing wirings 13e between the first substrate 11 and the second substrate 13 are formed of the first portion 11f1 and the second portion 11f2 of the first metal film and the second metal film 13b (13e) opposed thereto. The portions of the routing wirings 13e that reach the external mounting terminals 13g from the side surfaces 13c of the second substrate 13 are formed of the metal films that continue to the second metal film 13b.

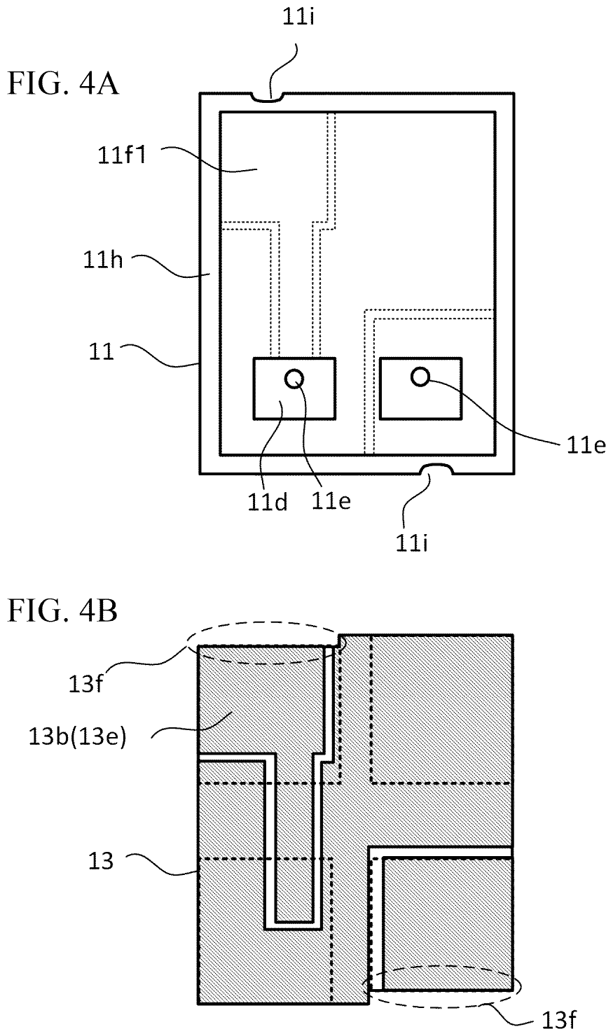

Next, the castellation 13f will be described with reference to FIG. 4A and FIG. 4B. FIG. 4A is a plan view of the first substrate 11 focusing on the castellation 13f, and FIG. 4B is a plan view of the second substrate 13 focusing on the castellation 13f. The castellations 13f are ones for routing the routing wirings 13e to the external mounting terminals 13g (see FIG. 1A and FIG. 1B). At a part of each of two opposite sides of the second substrate 13, the castellations 13f are formed in a cut-out shape that is slightly depressed from the edge to the center of the second substrate 13. Therefore, cut-out portions 11i are provided at portions of the first substrate 11 corresponding to the castellations 13f. While the number of the castellations is two in the illustrated example, there may be three or more.

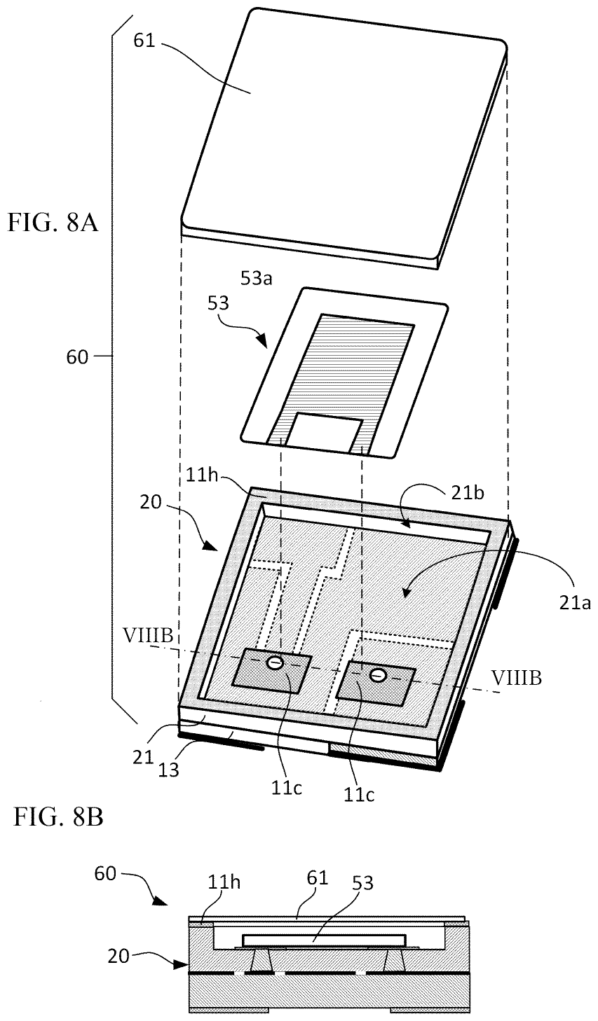

The external mounting terminals 13g are disposed on the fourth surface 13d and connected to the above-described routing wirings 13e. The external mounting terminals 13g are terminals used when the piezoelectric device (see FIG. 7A, FIG. 7B, FIG. 8A, and FIG. 8B) manufactured using the base 10 of this disclosure is mounted to various kinds of electronic equipment (not illustrated). In this example, while, as the external mounting terminals 13g, four terminals are indicated, the number of terminals is not limited to this. In this case, two terminals among the four terminals are examples of non-connection (NC). In a case where the piezoelectric device has a grounding structure, or the like, these non-connection terminals can be used as a grounding terminal.

### 1-2. Base 20 of Second Embodiment

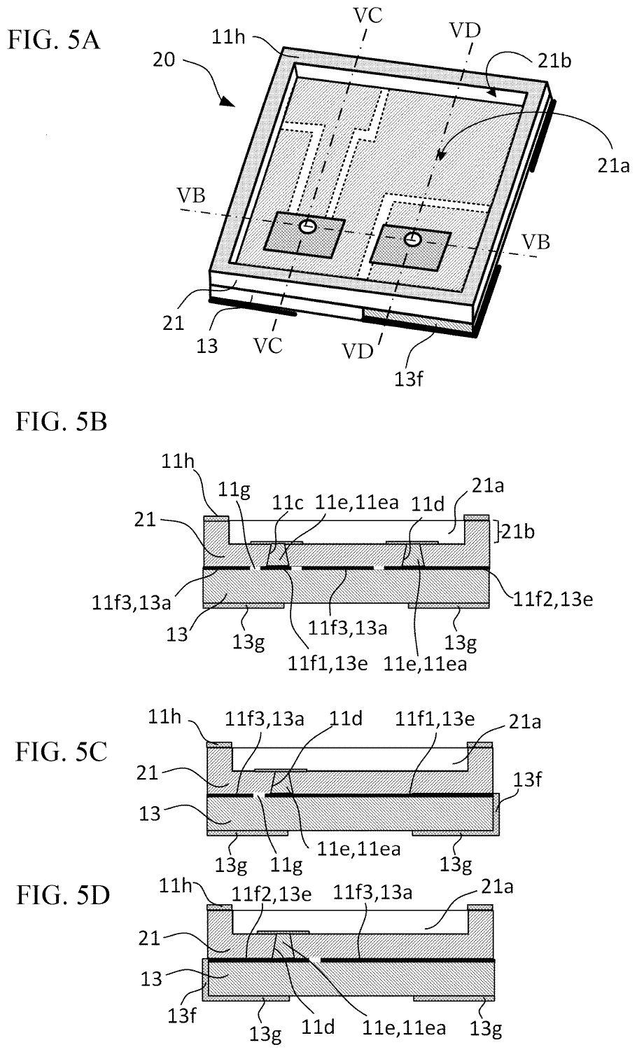

Next, a base 20 of a second embodiment will be described with reference to FIG. 5A to FIG. 5D. FIG. 5A is a plan view for describing the base 20 of the second embodiment, and FIG. 5B to FIG. 5D are cross-sectional views of the base 20 along lines VB-VB, VC-VC, and VD-VD in FIG. 5A, respectively.

The base 20 of the second embodiment is different from the base 10 of the first embodiment in that the first substrate 11 is provided with a depressed portion 21a in which a piezoelectric element is disposed and a dike 21b formed at a peripheral area of the depressed portion 21a. The depressed portion 21a has a quadrilateral planar shape, and the planar shape may be a square shape or a rectangular shape corresponding to the shape of the piezoelectric element mounted in the depressed portion 21a. The height and the width of the dike 21b can be set to any values corresponding to the design of the piezoelectric element mounted in the depressed portion 21a and considering ensuring of airtightness and the like.

### 1-3. Base 30 of Third Embodiment

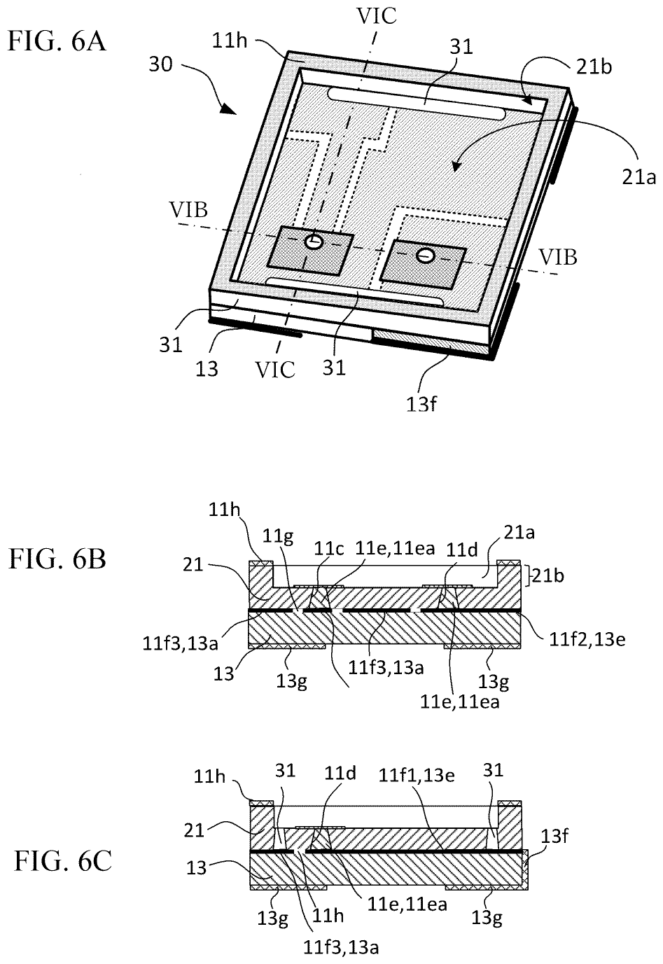

Next, a base 30 of a third embodiment will be described with reference to FIG. 6A to FIG. 6C. FIG. 6A is a plan view for describing the base 30 of the third embodiment, and FIG. 6B and FIG. 6C are cross-sectional views of the base 30 along lines VIB-VIB, VIC-VIC in FIG. 6A, respectively.

The base 30 of the third embodiment corresponds to a modification of the base 20 of the second embodiment provided with the depressed portion 21a in which the piezoelectric element (not illustrated) is disposed. Specifically, when the depressed portion 21a in which the piezoelectric element is to be disposed is formed at the first substrate, usually, a method in which a predetermined region of the first surface of a first substrate 21 is etched in a thickness direction of the first substrate 21 by a predetermined depth with a photolithography technique and a wet etching technique is used. However, in a case of wet etching, corners of the bottom surface of the depressed portion 21a are not flattened, and a part of the first substrate remains in the thickness direction at the corners. This remaining part decreases the plane dimension of the depressed portion 21a, narrows the region in which the piezoelectric element can be disposed, and consequently, dimensions of the piezoelectric element cannot be increased. Generally, since the improved characteristics can be expected of the piezoelectric element having a larger area, the remaining part is preferably not present. To solve this problem, the base 30 of the third embodiment has the following structure.

That is, the depressed portion 21a has a quadrilateral shape in plan view, and includes depressed portion shape correction portions 31 with holes toward the second substrate side in the proximity of a pair of sides of the quadrilateral shape of the bottom surface of the depressed portion. When the first substrate 21 is formed of, for example, a Z-cut plate of crystal, the depressed portion shape correction portions 31 are preferably provided in the proximity of a pair of sides parallel to the X-axis of crystal or a pair of sides parallel to the Y-axis of crystal among four sides of the quadrilateral shape of the bottom surface of the depressed portion 21a. When the depressed portion shape correction portions 31 are provided, since the side walls of the depressed portion at the portions become nearly vertical walls, the plane area in the proximity of the side portions of the depressed portion provided with the depressed portion shape correction portions 31 can be made larger than that a case without the depressed portion shape correction portions 31.

### 2. Embodiment of Piezoelectric Device

Next, an embodiment of the piezoelectric device will be described.

### 2-1. Piezoelectric Device of First Embodiment

First, with reference to FIG. 7A and FIG. 7B, a piezoelectric device 50 of the first embodiment will be described. FIG. 7A is a perspective view illustrating the exploded piezoelectric device 50 of the first embodiment, and FIG. 7B is a cross-sectional view of a cap-shaped lid member 51 with a depressed portion 51a for housing the piezoelectric element along a line VIIB-VIIB in FIG. 7A.

The piezoelectric device 50 of the first embodiment includes the base 10 of the first embodiment, for example, an AT-cut quartz-crystal vibrating piece 53 as the piezoelectric element 53 mounted to the base 10, and the cap-shaped lid member 51 connected to the base 10 at the position of the sealing pattern 11h to seal the piezoelectric element 53. Bonding can be performed with a brazing material, such as gold tin. The cap-shaped lid member 51 is preferably made of metal, and moreover is preferably a metal lid member considering linear expansion coefficients of the first substrate and the second substrate, for example, a lid member made of copper, nickel, or kovar. In consideration of the linear expansion coefficient, copper is most preferable. One denoted as 53a in FIG. 7A is an excitation electrode included in the piezoelectric element 53. The piezoelectric element 53 is connected and fixed to the mounting pad 11c by a conductive adhesive (not illustrated) at the position of the end portion of the excitation electrode 53a (the position of extraction wirings).

### 2-2. Piezoelectric Device of Second Embodiment

Next, with reference to FIG. 8A and FIG. 8B, a piezoelectric device 60 of the second embodiment will be described. FIG. 8A is a perspective view illustrating the exploded piezoelectric device 60 of the second embodiment, and FIG. 8B is a cross-sectional view of the piezoelectric device 60 along a line VIIIB-VIIIB in FIG. 8A.

The piezoelectric device 60 of the second embodiment includes the base 20 of the second embodiment and a flat plate-shaped lid member 61. The piezoelectric element 53 is connected and fixed to the mounting pad 11c by a conductive adhesive (not illustrated) at the position of the end portion of the excitation electrode 53a inside the depressed portion 21a of the base 20. The lid member 61 is connected to the sealing pattern 11h provided at a top surface of the dike 21b of the base 20 using a brazing material, such as gold tin.

While the above-described embodiments of the piezoelectric device are examples of a piezoelectric resonator, the disclosure of this application is applicable to a piezoelectric resonator with a temperature sensor to which a temperature sensor, such as a thermistor, is mounted together with the piezoelectric element, a piezoelectric oscillator to which an oscillator circuit is mounted together with the piezoelectric element, or a piezoelectric oscillator to which a temperature compensation circuit is mounted.

### 3. Embodiment of Manufacturing Method

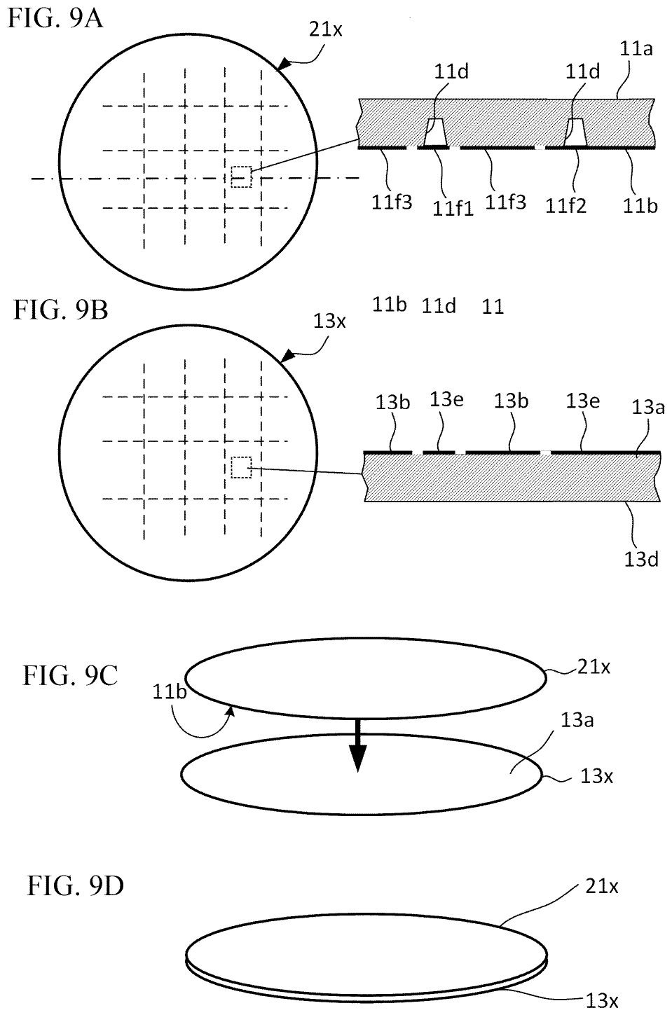

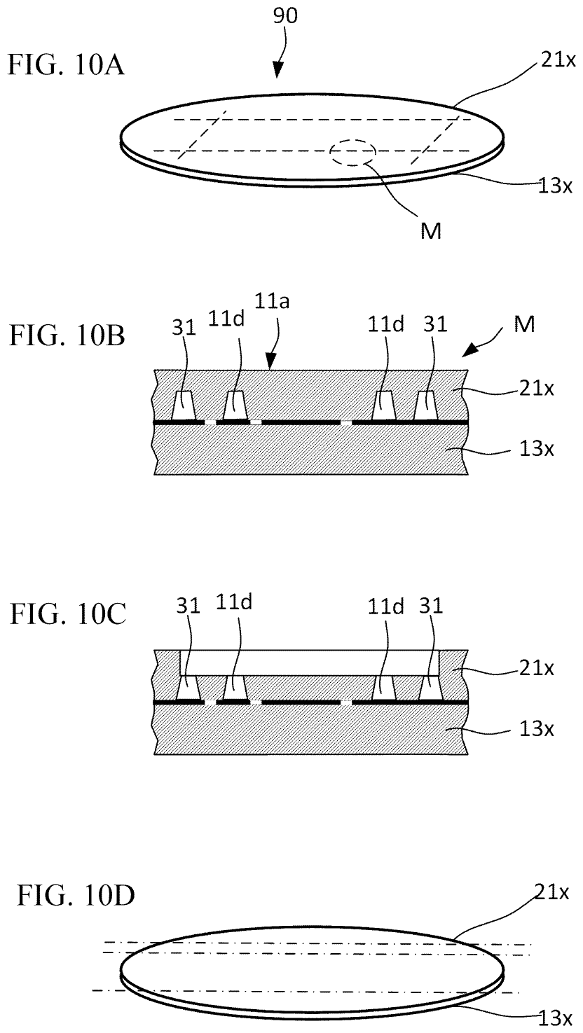

Next, an embodiment of a method for manufacturing a base for a piezoelectric device, which is a third disclosure of this application, will be described. The third disclosure relates to a manufacturing method of the base with the depressed portion 21a to which a piezoelectric element is mounted like the base 20 of the second embodiment. Moreover, in this manufacturing method, the base is manufactured in a state of a wafer where a large number of the bases are arranged in a matrix. FIG. 9A to FIG. 9D and FIG. 10A to FIG. 10D are process drawings for describing the method, and drawings for especially describing a step of forming a contact hole. In FIG. 9A to FIG. 9D and FIG. 10A to FIG. 10D, some drawings illustrate the whole wafer, and some drawing illustrate an enlarged part of the wafer.

First, a wafer 21x for forming a first substrate is prepared. The wafer 21x has a first surface and a second surface opposed thereto, and is formed of glass or crystal. A wafer 13x for forming a second substrate is prepared. The wafer 13x has one principal surface as a third surface and a principal surface opposed to the third surface as a fourth surface, and is formed of a material identical to that of the wafer 21x for forming the first substrate. For each of the wafers 21x and 13x, a crystal wafer or a glass wafer, for example, having a circular or quadrilateral planar shape and a predetermined thickness is used.

Subsequently, the wafer 21x for forming the first substrate is provided with holes 11d for contact holes. The holes 11d are formed from the second surface 11b toward the first surface 11a, and closed halfway in the thickness direction of the wafer 21x for forming the first substrate. Subsequently, first metal films 11f1, 11f2, and 11f3 for intermetallic bonding are formed at a peripheral area of the holes 11d for the contact holes on the second surface of the wafer 21x for forming the first substrate (FIG. 9A).

The formation of the contact holes 11d and the formation of the first metal films can be performed by a photolithography technique, a wet etching technique, and a film forming technique. As the film forming technique, for example, a sputtering method may be used.

In the formation of the holes 11d for the contact holes, by forming the holes (see FIG. 10B) for the depressed portion shape correction portions 31 described for the base 30 of the third embodiment, a manufacturing process of the base of the third embodiment can be performed. Obviously, when the depressed portion shape correction portion 31 is not necessary, the hole for the depressed portion shape correction portion 31 does not need to be formed.

Subsequently, on the third surface 13a of the wafer 13x for forming the second substrate, second metal films 13b and 13e for causing the intermetallic bonding cooperatively with the first metal films are formed (FIG. 9B). The formation of the second metal films 13b and 13e can be performed by a photolithography technique, a wet etching technique, and a film forming technique.

Subsequently, the wafer 21x for forming the first substrate in which the holes for the contact holes, the first metal films, and the like have been formed is brought in contact with the wafer 13x for forming the second substrate in which the second metal films have been formed via the second surface 11b and the third surface 13a (FIG. 9C), and the wafer 21x for forming the first substrate and the wafer 13x for forming the second substrate are bonded by intermetallic bonding between the first metal film and the second metal film (FIG. 9D, FIG. 10A). The intermetallic bonding is typically performed by applying a pressure to the wafers 13x and 21x and heating them. A part M in FIG. 10A corresponds to a formation region of one base.

The depressed portion 21a that houses the piezoelectric element and has the bottom surface connected to the holes 11d for the contact holes is formed from the first surface 11a side of the wafer 21x for forming the first substrate of a structure 90 (FIG. 10A) after the above-described bonding (FIG. 10B, FIG. 10C). By finishing this process, the contact holes 11d are coupled to the depressed portion 21a, and the original contact holes 11d are obtained. When the holes for the depressed portion shape correction portions 31 are formed, the depressed portion shape correction portions 31 can be formed at predetermined positions of the depressed portion 21a (FIG. 10B, FIG. 10C).

Subsequently, using the photolithography technique, the wet etching technique, and the film forming technique, the contact hole wiring 11e, the plating film 11ea as necessary, the mounting pad 11c, the routing wiring 13e, and the external mounting terminal 13g (see FIG. 2A to FIG. 2D) are formed. Thus, a wafer 21x in which a large number of the bases 20 of the second embodiment are arranged in a matrix can be obtained (FIG. 10D).

To embody the first disclosure, the first substrate is preferably a flat plate, and includes a sealing pattern for sealing along an edge of the first surface of the first substrate. In a case of this preferable example, the novel base according to the first disclosure that is a flat type one can be provided. Furthermore, the use of the base and a cap-shaped lid member enables achieving a novel piezoelectric device including a flat plate base and a cap-shaped lid member (for example, see FIG. 8A and FIG. 8B).

To embody the first disclosure, the first substrate preferably includes a depressed portion that houses the piezoelectric element and a dike at a peripheral area of the depressed portion on the first surface side. In the case of this preferable example, the novel base according to the first disclosure configured to include the piezoelectric element can be provided. Furthermore, the use of the base and a flat plate-shaped lid member enables achieving a novel piezoelectric device including a base configured to include the piezoelectric element and a flat plate-shaped lid member (see FIG. 9A to FIG. 9D).

According to an aspect of this disclosure, there is provided a piezoelectric device as a second disclosure of the application. The piezoelectric device includes the base according to the first disclosure, a piezoelectric element connected and fixed to a mounting pad of the base by a conductive member, and a lid member that is bonded to the base and seals the piezoelectric element.

According to an aspect of this disclosure, there is provided a method for manufacturing a base for a piezoelectric device as a third disclosure of the application. The method includes, in manufacturing the base according to the first disclosure including a depressed portion that houses a piezoelectric element and a dike at a peripheral area of the depressed portion:
(a) forming a hole for a contact hole at a first substrate, the first substrate having a first surface and a second surface opposed to the first surface and being formed of glass or crystal, the hole being provided from the second surface toward the first surface and closed halfway in a thickness direction of the first substrate;
(b) forming a first metal film for intermetallic bonding at a peripheral area of the hole for the contact hole on the second surface;
(c) forming a second metal film for causing the intermetallic bonding cooperatively with the first metal film on a third surface of a second substrate, the second substrate having one principal surface defined as the third surface and a principal surface opposed to the third surface defined as a fourth surface and being formed of a material identical to a material of the first substrate;
(d) bonding the first substrate in which the hole for the contact hole and the first metal film have been formed and the second substrate in which the second metal film has been formed by bringing the second surface in contact with the third surface to cause the intermetallic bonding between the first metal film and the second metal film; and
(e) forming a depressed portion from the first surface side of a structure after the bonding, the depressed portion housing a piezoelectric element and having a bottom surface connected to the hole for the contact hole.

According to the base of the first disclosure of this application, a base for a piezoelectric device having a structure in which a first substrate and a second substrate formed of glass or crystal are stacked by intermetallic bonding is configured. Moreover, a base having a structure in which a piezoelectric element mounted to the base can be connected to an external mounting terminal by a contact hole wiring disposed at the first substrate, a part of a metal film used for the intermetallic bonding, and a routing wiring disposed at the second substrate using a castellation is achieved. Moreover, since a peripheral area of the contact hole has a structure surrounded by the intermetallic bonding between the first metal film and the second metal film, a contact hole region which often causes a problem of airtightness reduction is sealed by the intermetallic bonding. Moreover, since the first substrate and the second substrate are formed of the same material, and physical properties, such as a thermal expansion coefficient, are the same, an advantage in airtightness is provided also in this respect.

Moreover, the contact hole has an opening area on the second surface side larger than an opening area on the first surface side. Generally, the piezoelectric element is connected to the base by a silicone-based conductive adhesive. Then, when the piezoelectric element is bonded to the base, to improve the electrical connection between the conductive adhesive and an electrode of the piezoelectric element, the piezoelectric element is pressed to the base side from the upper surface of the piezoelectric element. At this time, since the contact hole having the opening area on the second surface side larger than the opening area on the first surface side causes the conductive adhesive to easily reach the contact hole wiring and the second metal film on the second substrate, the reliability of the electrical connection of the piezoelectric element can be expected to be improved.

Therefore, even with the stacked structure of the first substrate and the second substrate formed of glass or crystal, the base that allows ensuring the airtightness and attempting the improvement of the wiring structure can be achieved.

Each of the glass and the crystal constituting the first substrate and the second substrate can be processed by a photolithography technique, and therefore, the processing can be performed with relatively high accuracy, and the glass and the crystal are both relatively inexpensive as the material cost. Accordingly, the base with high accuracy can be achieved at a low cost.

According to the piezoelectric device as the second disclosure of this application, a novel piezoelectric device using the base having the above-described novel structure can be achieved.

According to the disclosure of the method for manufacturing the base for the piezoelectric device as the third disclosure of this application, the base according to the first disclosure including the depressed portion that houses the piezoelectric element and the dike at the peripheral area of the depressed portion can be easily manufactured.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A base comprising:
a first substrate having a first surface and a second surface opposed to the first surface, the first substrate being formed of glass or crystal;
a contact hole and a contact hole wiring extending from the first surface to the second surface;
a first metal film disposed in a region including a peripheral region of the contact hole on the second surface;
a second substrate formed of a material identical to a material of the first substrate and bonded to the first substrate by intermetallic bonding;
a second metal film disposed on a third surface as a surface of the second substrate on a first substrate side, the second metal film constituting the intermetallic bonding cooperatively with the first metal film; and
a routing wiring that reaches a fourth surface of the second substrate as an opposite surface of the third surface from the contact hole wiring via the third surface and a side surface of the second substrate, wherein
the contact hole has an opening area on a second surface side larger than an opening area on a first surface side.

2. The base according to claim 1, wherein
the contact hole wiring has a superficial layer of a plating film.

3. The base according to claim 1, wherein
the contact hole wiring is disposed to reach also a region corresponding to an edge of the contact hole on the first surface, and
the contact hole wiring has a superficial layer of a plating film.

4. The base according to claim 1, comprising
a mounting pad for mounting a piezoelectric element at a peripheral area of the contact hole on the first surface, wherein
the contact hole wiring and the mounting pad have superficial layers of plating films.

5. The base according to claim 1, wherein
a part of the routing wiring is the first metal film and the second metal film.

6. The base according to claim 1, wherein
the first substrate is a flat plate, and includes a sealing pattern for sealing along an edge of the first surface of the first substrate.

7. The base according to claim 1, wherein
the first substrate includes a depressed portion that houses a piezoelectric element and a dike at a peripheral area of the depressed portion on the first surface side.

8. The base according to claim 1, wherein
the first substrate includes a depressed portion that houses a piezoelectric element and a dike at a peripheral area of the depressed portion on the first surface side, and
the depressed portion has a quadrilateral shape in plan view, and includes depressed portion shape correction portions in proximity of a pair of sides of the quadrilateral shape of a bottom surface of the depressed portion, and the depressed portion shape correction portions are formed of holes toward a second substrate side.

9. The base according to claim 1, wherein
the first substrate is formed of a Z-cut plate of crystal, and includes a depressed portion that houses a piezoelectric element and a dike at a peripheral area of the depressed portion on the first surface side, and
the depressed portion has a quadrilateral shape in plan view, and includes depressed portion shape correction portions in proximity of a pair of sides parallel to an X-axis of the crystal or a pair of sides parallel to a Y-axis of the crystal of the quadrilateral shape of a bottom surface of the depressed portion, and the depressed portion shape correction portions are formed of holes toward a second substrate side.

10. The base according to claim 1, wherein
each of the first metal film and the second metal film is a laminated film of a chrome film as a foundation film, a nickel film or a nickel-tungsten alloy film as an intermediate film, and a gold film as an upper layer film, or a laminated film of a titanium film as a foundation film and a gold film as an upper layer film.

11. The base according to claim 1, wherein
each of the first metal film and the second metal film is a laminated film of a chrome film as a foundation film, a nickel film or a nickel-tungsten alloy film as an intermediate film, and a gold film as an upper layer film, and
a laminated film of a titanium film and a gold film laminated on the titanium film is provided on the upper layer film.

12. The base according to claim 1, wherein
the contact hole includes two contact holes of a first contact hole and a second contact hole,
each of the first metal film and the second metal film includes a first portion two-dimensionally surrounding a peripheral area of the first contact hole, a second portion two-dimensionally surrounding a peripheral area of the second contact hole, and a third portion covering a remaining region, and
the base includes an insulation region that insulates between the first portion, the second portion, and the third portion.

13. The base according to claim 1, wherein
each of the first substrate and the second substrate is formed of an AT-cut plate of crystal or a Z-cut plate of crystal.

14. A piezoelectric device comprising:
the base according to claim 1;
a piezoelectric element directly or indirectly connected to the contact hole wiring by a conductive member; and
a lid member that is bonded to the base and seals the piezoelectric element.

15. The piezoelectric device according to claim 14, wherein
the piezoelectric element is an AT-cut quartz-crystal vibrating piece.

16. A method for manufacturing a base for a piezoelectric device, comprising,
in manufacturing the base according to claim 7:
forming a hole for a contact hole at a first substrate, the first substrate having a first surface and a second surface opposed to the first surface and being formed of glass or crystal, the hole being provided from the second surface toward the first surface and closed halfway in a thickness direction of the first substrate;
forming a first metal film for intermetallic bonding at a peripheral area of the hole for the contact hole on the second surface;
forming a second metal film for causing the intermetallic bonding cooperatively with the first metal film on a third surface of a second substrate, the second substrate having one principal surface as the third surface and a principal surface opposed to the third surface as a fourth surface and being formed of a material identical to a material of the first substrate;
bonding the first substrate in which the hole for the contact hole and the first metal film have been formed and the second substrate in which the second metal film has been formed by bringing the second surface in contact with the third surface to cause the intermetallic bonding between the first metal film and the second metal film; and
forming a depressed portion from the first surface side of a structure after the bonding, the depressed portion housing a piezoelectric element and having a bottom surface connected to the hole for the contact hole.

17. The method for manufacturing the base for the piezoelectric device according to claim 16, wherein
the depressed portion that houses the piezoelectric element has a quadrilateral shape in plan view, and
when the hole for the contact hole is formed at the first substrate, holes for depressed portion shape correction are formed toward the first surface in a region that is a formation-scheduled region of the quadrilateral shaped-depressed portion and that corresponds to a pair of sides of the quadrilateral shape of a bottom surface of the depressed portion.
